(19) United States
(12) Patent Application Publication
(10) Pub. No.: US 2017/0149385 A1
(43) Pub. Date: May 25, 2017

(54) FAST STARTING CRYSTAL OSCILLATOR WITH LOW VARIATION

(71) Applicant: Infineon Technologies AG, Neubiberg (DE)

(72) Inventors: Mattias Welponer, Graz (DE); Michaek Aichner, Strassen (DE)

(21) Appl. No.: 14/950,220

(22) Filed: Nov. 24, 2015

(51) Int. Cl. H03B 5/06; H03B 5/36

(52) U.S. Cl. CPC H03B 5/06; H03B 5/36

(57) ABSTRACT

An oscillation circuit includes an oscillation system and a boost circuit configured to initiate an oscillation in the oscillation system. The boost circuit is configured to excite the oscillation system with an excitation signal having a frequency that varies from an initial frequency to a final frequency, the initial frequency and the final frequency defining a frequency band. The resonant frequency of the oscillation system resides within the frequency band. The boost circuit is turned off after the ramp has finished.

### FIELD

The present disclosure is directed to a circuit for initiating oscillation in a crystal oscillator structure or other oscillation system and a corresponding method.

### BACKGROUND

Many electrical circuits employ a reference frequency signal for various purposes. If a precise and frequency-stable reference frequency is required usually a high Q (quality factor) oscillator such as a crystal or comparable type oscillator structure is used. These oscillator types typically show a long start up time what influences the lifetime of battery operated systems.

### BRIEF DESCRIPTION OF THE DRAWINGS

FIG. 1 is a schematic diagram illustrating a boost circuit for initiating an oscillation system according to one embodiment of the disclosure.

FIG. 2 is a block level diagram illustrating various circuits together configured to form the boost circuit of FIG. 1 according to one embodiment of the disclosure.

FIG. 3 is a graph illustrating a current ramp signal according to one embodiment of the disclosure.

FIG. 4 is a schematic diagram illustrating a circuit configured to generate a current ramp signal according to one embodiment of the disclosure.

FIG. 5 is a schematic diagram illustrating an oscillator circuit that is configured to receive a current ramp signal and generate a variable frequency output signal that may operate as an excitation signal for the oscillation system of FIG. 1 according to one embodiment of the disclosure.

FIG. 6 is a graph illustrating a triangular voltage waveform showing a changing voltage slope that corresponds to the current ramp signal according to one embodiment of the disclosure.

FIG. 7 is a graph illustrating a start-up time for an oscillation system that does not employ a boost circuit.

FIG. 8 is a graph illustrating the start-up time for an oscillation system that does employ a boost circuit in accordance with one embodiment of the disclosure.

FIGS. 9-11 are flow chart diagrams illustrating various acts in initiating a stable reference frequency in an oscillation system according to one embodiment of the disclosure.

### DETAILED DESCRIPTION

The present disclosure will now be described with reference to the attached drawing figures, wherein like reference numerals are used to refer to like elements throughout, and wherein the illustrated structures and devices are not necessarily drawn to scale.

Systems, methods, devices and embodiments are provided that quickly and efficiently establish a stable reference frequency.

As stated above, crystal oscillators are often employed as a frequency reference in various type of electrical circuits. Typically, a crystal oscillator structure is excited into its resonant oscillation frequency via noise. An amount of time needed for the crystal oscillator structure to reach its stable resonant oscillation frequency is sometimes referred to as the “oscillation build-up time.”

In the case of quartz crystals as crystal oscillator structures, the oscillation build-up time can be more than 3 ms and a substantial variation in the oscillation build-up time, due to tolerances and being initiated via noise which is variable, can require a design to wait up to 10 ms to ensure a stable reference frequency is established under all conditions. The long “original” start-up time together with this additional wait guard band can result in reduced battery lifetime in portable applications. Thus conventional crystal oscillators often suffer a trade-off between the start-up time start-up variation and circuit power consumption.

The present disclosure is directed to a crystal oscillator structure and a boost circuit that is configured to excite the crystal oscillator to quickly reach its stable resonant frequency and thus both reduce the oscillator start-up time as well as its start-up time variability. The boost circuit operates to generate an excitation signal having a frequency that varies from an initial frequency to a final frequency. The range of frequencies between the initial frequency and the final frequency defines a frequency band, wherein the resonant frequency of the crystal oscillator structure resides within the frequency band. The use of the excitation signal having the varying frequency leads to a faster oscillation build-up of the crystal oscillator structure as the targeted stimulation oscillates at a significant signal amplitude at the resonant frequency and therefore energy is brought into the crystal. Consequently, the oscillation of the crystal oscillator structure is not started from noise and consequently the large fluctuation in the oscillator build-up time is greatly reduced.

In one embodiment of the disclosure, in a method of starting or initiating the operation of a crystal oscillator structure, a frequency ramp excitation signal is generated and applied to the crystal oscillator structure. The frequency ramp excitation signal causes the crystal oscillator structure to oscillate at its resonant frequency, as the resonant frequency of the crystal oscillator structure is a frequency included within a range of frequencies covered by the frequency ramp excitation signal. Consequently, energy is introduced into the crystal oscillator structure after a pass through of the frequency ramp excitation. After the pass through, the boost circuit that generates the frequency ramp excitation signal is switched off and the crystal oscillator structure continues to oscillate via an oscillator circuit in which the crystal oscillator structure resides. In one embodiment the oscillator circuitry comprises a Pierce type oscillator, however, other oscillator circuitry may be employed and all such alternative oscillator circuits may be utilized and are contemplated as falling within the scope of the present disclosure.

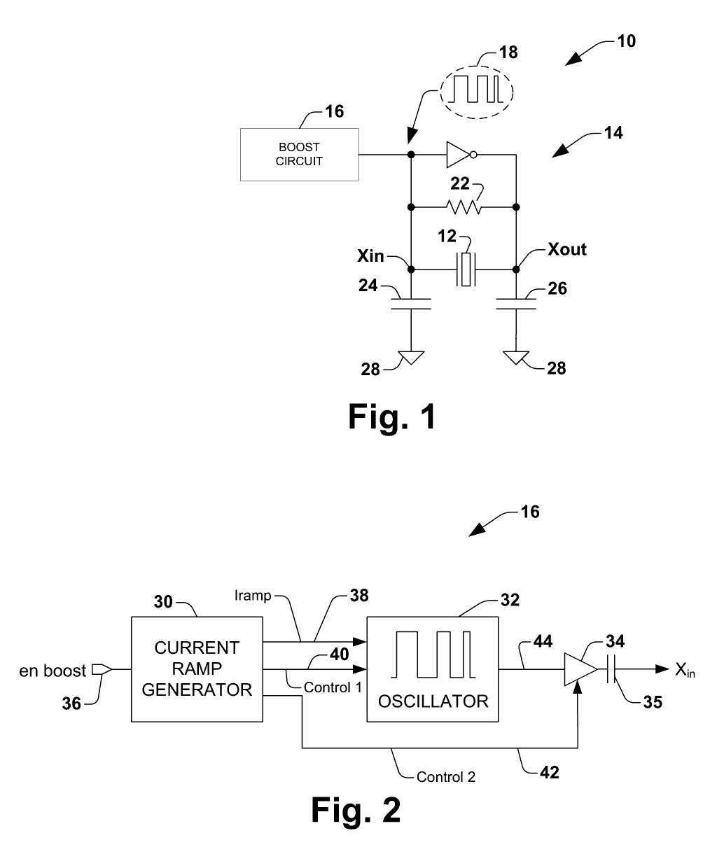

Turning now to the figures, FIG. 1 is a simplified schematic diagram of an oscillator circuit 10 that comprises a crystal 12 within an oscillating circuitry 14, such as a Pierce oscillator. The oscillator circuit 10 further comprises a boost circuit 16 coupled to the oscillation circuitry 14. The boost circuit 16 is configured to generate an excitation signal 18 that is operable to establish a stable reference frequency of the crystal oscillator structure at its resonant frequency. In the example embodiment of FIG. 1, the oscillating circuitry 14 comprises a Pierce oscillator having an inverter 20 that receives the excitation signal 18. A bias resistor 22 is coupled in parallel with the inverter 20 and operates to bias the inverter 20 in its linear region of operation, thereby causing the inverter to operate as a high gain inverting amplifier. The crystal oscillator structure 12 is in parallel with the resistor 22 and the inverter 20 and forms the terminals Xin, Xout of the oscillator circuit 10. The circuit 10 further comprises two capacitors 24, 26 coupled between the terminals Xin, Xout and a reference potential 28, such as ground, for example. The crystal structure 12 in combination with the capacitors 24 and 26 form a band pass filter and provides a 180 degree phase shift and a voltage gain from the output Xout to the input Xin at a small region around the resonant frequency of the crystal.

As can be seen in FIG. 1, the excitation signal 18 from the boost signal comprises a frequency ramp that varies from an initial frequency f₁ to a final frequency fₙ, wherein the range of frequencies defined by f₁ and fₙ defines a frequency band. In one embodiment f₁<fₙ and the frequency ramp comprises a signal exhibiting an increasing frequency. In another embodiment f₁>fₙ and the frequency ramp of the excitation signal exhibits a decreasing frequency. Further, in one embodiment the frequency ramp increases or decreases in a generally linear fashion, however non-linear variations in frequency are also contemplated as falling within the scope of the disclosure.

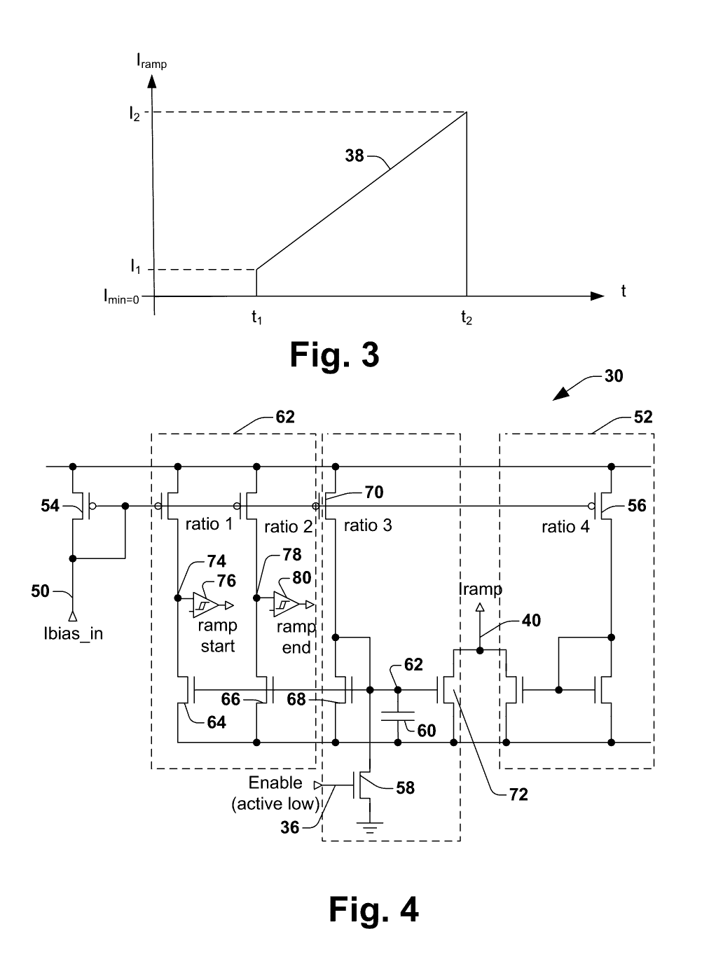

FIG. 2 is a schematic diagram illustrating in greater detail one example embodiment of the boost circuit 16 of FIG. 1. The boost circuit 16 comprises a current ramp circuit (i.e., a current ramp generator) 30 and a current controlled oscillator circuit (e.g., a current controlled RC oscillator) 32. The boost circuit 16 further comprises a tri-state buffer 34 and a decoupling capacitor 35. Upon receipt of a boost enable signal (en boost) 36 the current ramp generator 30 is activated. The current ramp circuit 30 is configured to generate a current ramp signal 38 that varies from a first, initial current value I₁ to a second, final current value I₂. In one embodiment the current ramp signal 38 varies from the first initial current I₁ to the second final current I₂ over a time period t₂-t₁, as illustrated in FIG. 3. In the embodiment shown in FIG. 3, I₁<I₂ and the current of the current ramp signal increases in a substantially linear fashion, resulting (as will be more fully appreciated later) in a frequency ramp signal that increases in frequency. Further, as will be seen later in greater detail, the frequency ramp signal 18 of FIG. 1 increases from its initial frequency at t₁ to its final frequency at t₂ (comprising a plurality of pulses having different frequencies during the time period t₂-t₁.

Still referring to FIG. 2, the RC oscillator circuit 32 receives the current ramp signal 38 from the current ramp circuit 30 as well as a control signal 40 (e.g., control 1) that operates to start and stop the RC oscillator circuit 32, respectively. In one embodiment, the current ramp circuit 30 outputs a second control signal 42 (e.g., control 2) that operates to activate/deactivate a tri-state buffer 34 that receives an output 44 of the RC oscillator circuit 32 and selectively passes the output signal 44 to the oscillation circuitry 14 containing the crystal oscillator structure 14 of FIG. 1. In the above manner, the tri-state buffer 34 operates as a switch to selectively stimulate the crystal oscillator structure 12 only during actual ramping, according to one embodiment.

FIG. 4 is a schematic circuit diagram illustrating in greater detail one embodiment of a current ramp circuit 30 according to the present disclosure. The current ramp circuit 30 receives a bias reference current Ibias_in at an input 50, wherein Ibias_in serves as a reference current for a series of current mirror branches. For example a minimum current portion 52 of the current ramp circuit 30 generates the initial current I₁, which corresponds generally to Ibias_in (or is otherwise proportional to the bias current) based on the width-to-length (W/L) ratio between the bias current mirror transistor 54 and the minimum current mirror branch transistor 56. This initial current I₁ is mirrored over to the output mode 40 as the Iramp current. Alternatively, and advantageously, in one embodiment the Ibias path is open when the boost circuit is deactivated such that the initial current Iₘᵢₙ=0, which allows for less power consumption and then jumps to I₁ upon activation of the boost circuit, as illustrated in FIG. 3.

Normally, when deactivated, the current ramp circuit 30 receives the en boost signal as a high level (H), which causes a start transistor 58 to be on, thus causing a capacitor 60 to be discharged and the NMOS devices 64, 66 and 68 to be off. When the en boost signal goes low (L) at 36, the start transistor 58 turns off. Current from the ratio 3 transistor 70 causes a gradual charging of the capacitor 60, causing the node 62 to increase, resulting in the Iramp current 40 to increase, based on a transconductance of the transistor 72.

As transistor 64 begins to conduct due to a charging of the capacitor 60 increasing the node voltage 62, the voltage at node 74 decreases, causing a ramp start comparator 76 to trip and the ramp start signal goes high, indicating a beginning of the current ramp time period. As the capacitor 60 continues to charge, the transistor 66 is also beginning to conduct and the node 78 also continues to get pulled low, and due to the lower threshold of the ramp end comparator 80, the ramp end comparator 80 gets tripped and goes high, indicating an end of the current ramp. So when the ramp start signal is high and the ramp end signal is low, the current is in the process of ramping and when both the ramp start signal and the ramp end signal are high the current ramp has finished.

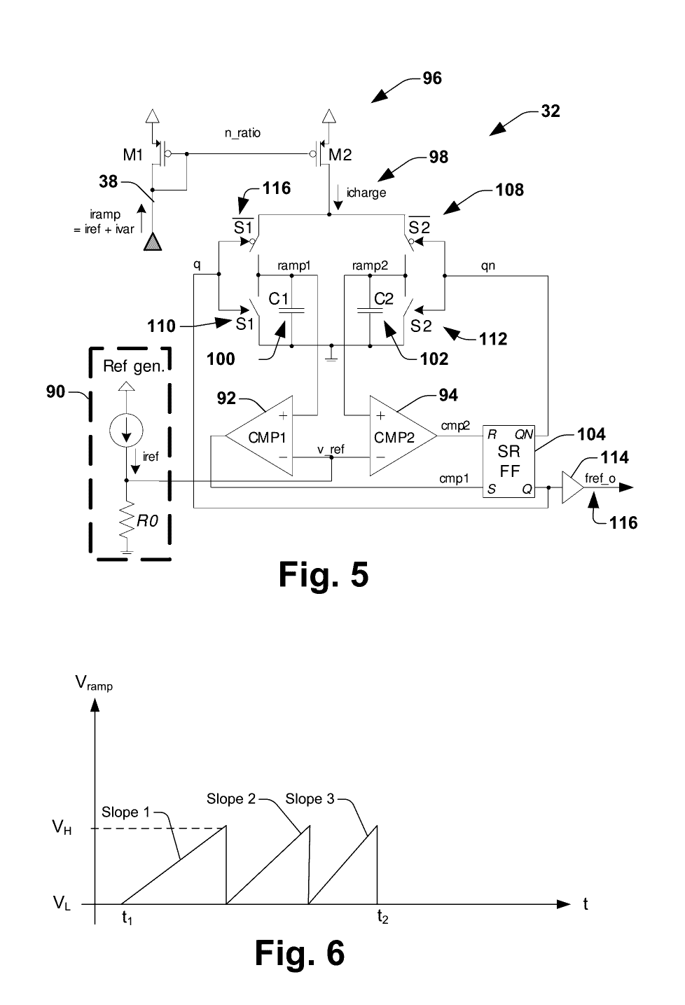

The oscillator circuit 32 of the boost circuit 16 of FIG. 2 is illustrated in greater detail in FIG. 5 in accordance with one embodiment of the disclosure. Initially, at a high level, the oscillator circuit 32 in one embodiment comprises an RC oscillator circuit and includes a voltage reference generation circuit 90 that provides a reference voltage v_ref to a pair of comparator circuits CMP1 92 and CMP2 94. The ramp current Iramp 38 is received from the current ramp generator 30 of FIG. 4 and mirrored via a current mirror circuit 96 (M1 and M2) to form a charging current i_{charge} 98. Based on a tripping of the comparators 92 and 94 the charging current 98 is alternatively directed to first and second ramping capacitors 100, 102. As will be discussed in greater detail below, the comparators 92 and 94 together with the SR-Flip Flop 104 operate to alternatively switch the ramping capacitors 100, 102 between a charging mode and a discharging mode. As will be further appreciated, as the ramp current 38 increases the charging current 98 also increases which results in a rate of the charging of the capacitors to also increase. The increased charging rate of the capacitors 100, 102 is then employed to generate a voltage signal that increases in frequency in accordance with the current ramp signal 38.

More particularly, the RC oscillator 32 receives the Iramp current signal 38 which is composed of the reference or minimum current portion consisting of I₁ and the variable portion that consists of the variable portion that varies between 0 and I₂-I₁. In the above manner, the ramp current varies between the values I₁ and I₂. In this example, the ramp current signal 38 increases in a generally linear fashion, however, other variations are possible and are contemplated as falling within the scope of the present disclosure. The ramp current Iᵣₐₘₚ 38 is mirrored via a current mirror circuit 96 composed of transistors M1 and M2 to form the charging current 98, wherein I_{charge} 98 is a ratio of Iᵣₐₘₚ 38 based on the relative width-to-length ratios of the transistors M1 and M2. The charging current I_{charge} 98 is directed along one of two conduction paths based on a state of the switches S1, S1(bar) and S2, S2(bar). The on/off state of the switches S1 and S2 is dictated by the control signals q and qn that are outputs of an SR flip flop 104. When the reset output of the flip flop 104 is high (qn=H and q=L) the S1(bar) switch 116 is closed and the S2(bar) switch 108 is open, while the S1 switch 110 is open and the S2 switch 112 is closed. In this configuration, the charging current I_{charge} 98 charges the first charging capacitor while the S2 switch 112 ensures the second charging capacitor C2 is discharged. This causes the voltage at the ramp1 node to increase as the first capacitor charges, wherein the rate at which the ramp1 node increases is a function of the magnitude of the charging current I_{charge} 98 (and thus also a function of the ramp current 38).

Once the voltage at ramp exceeds the reference voltage v_ref, the first comparator 92 trips and the resultant voltage at cmp1 causes the flip flop 104 to set, such that q is now high and qn is low. This causes the S1(bar) switch 110 to close and the S2 switch 112 to open. In this switch configuration, the first charging capacitor C1 is discharged through S1 110, while the second charging capacitor C2 is charged with the charging current I_{charge} 98 through S2(bar) 108. It should be noted that since the charging current 98 is ramping, the charging current for C2 in this embodiment is greater than it was previously for the charging of C1, causing the rate at which the voltage at the ramp2 node increases to be greater than the rate at which ramp1 previously increased. Consequently, the voltage at ramp2 will trip the second comparator 94 more quickly and thus the flip flop 104 will be reset more quickly. A combination of the voltages at ramp1 and ramp2 are provided in FIG. 6 as one example. In it, one can see that for three example cycles, the slope of each successive voltage ramp increases, wherein slope3>slope 2>slope 1, which corresponds to the higher rate of charging due to an increased charging current. The resultant voltage ramp signal of FIG. 6 then gets input to the comparators 92 and 94 of FIG. 5, which drive the set/reset inputs of the SR flip flop 104, resulting in a generally square wave form that varies in frequency in a manner that corresponds to the changing rate of charging of the capacitors 100 and 102 in FIG. 5.

Thus it can be seen how the resultant signal 116 at the output (e.g., the output of a buffer 114) constitutes a square wave signal that has a frequency that varies (e.g., increases) in a manner that corresponds to the current ramp signal 38, wherein the initial frequency of the output (i.e., the excitation signal 18 of FIG. 1) corresponds to I₁ (e.g., a non-zero current) and the final, maximum frequency corresponds to I₂.

As highlighted above, the excitation signal 18 (i.e., signal 116 of FIG. 5) is configured to vary between two frequency values that define a frequency band within which the resonant frequency of the crystal structure 12 resides. Consequently, the ramp current 38 of FIG. 3 (generated by the circuit 30 of FIG. 4, for example) is configured to vary between two current values I₁ and I₂ that ensure the above frequency range. In one advantageous embodiment the frequency range of the excitation signal 18 is relatively narrow about the expected or estimated resonant frequency of the crystal structure 12, however, varying range sizes may be employed and are contemplated by the present disclosure.

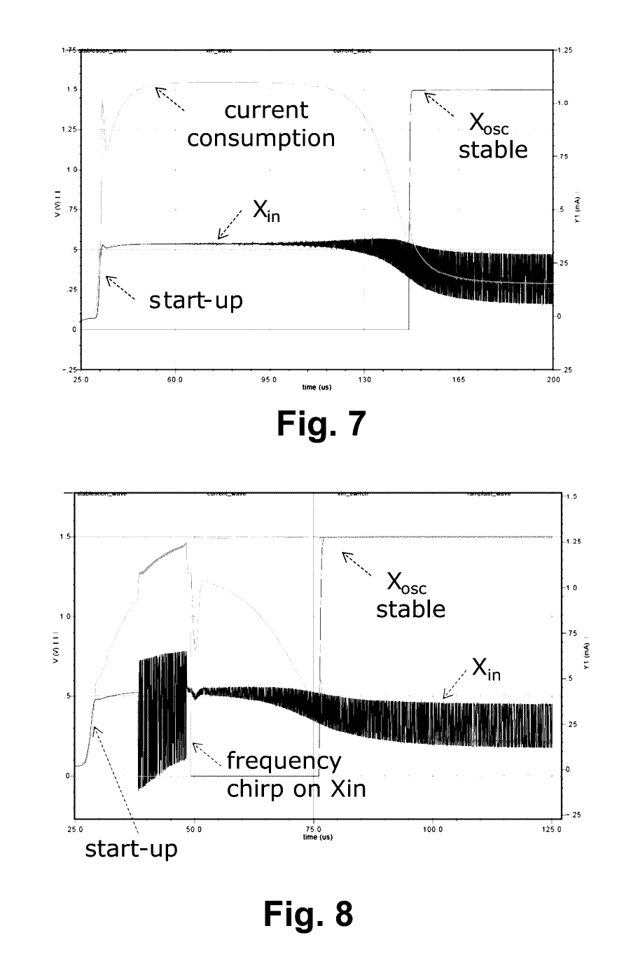

Some of the benefits of the boost circuit of the present disclosure may be seen in the comparison of FIGS. 7 and 8. In FIG. 7 one can see that it takes about 120 microseconds between an initial start of the crystal and the time it actually reaches a stable oscillation point for a conventional type crystal oscillator circuit that employs noise for start-up, for example. In contrast, FIG. 8 shows a time period of about 45 microseconds between initiation of the boost circuit and the establishment of a stable oscillation or reference frequency, which is a reduction of almost 3× in this example. Further, as can be seen in FIGS. 7 and 8, the boost circuit of the present disclosure in FIG. 8 consumes less current in the start-up time period, thus resulting in an improvement in reducing power consumption.

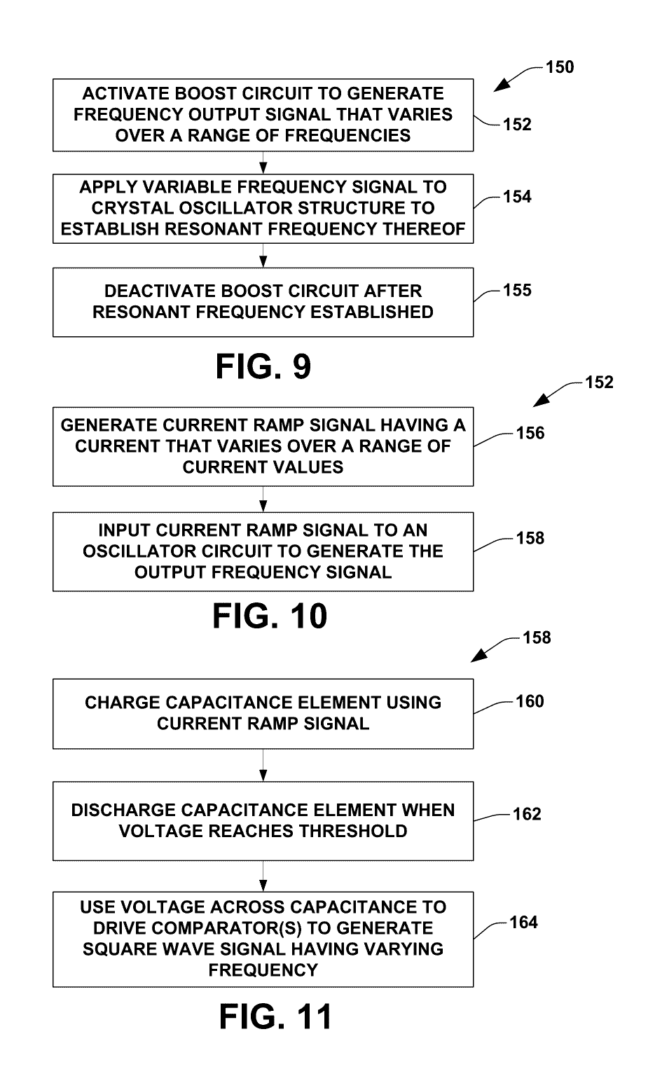

The present disclosure also includes a method of initiating oscillation in a crystal oscillator structure. More particularly, FIG. 9 is a flow chart diagram illustrating such a method 150.

While the method is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the disclosure herein. Also, one or more of the acts depicted herein may be carried out in one or more separate acts and/or phases.

At 152 of FIG. 9 an act of activating a boost circuit to generate an output frequency signal occurs. The generated output frequency signal varies in frequency from an initial frequency to a final frequency, thereby defining a range of frequencies. The method continues at 154 by applying the output frequency signal to the crystal oscillator structure, wherein a resonant frequency of the crystal oscillator structure is within the range of frequencies defined by the boost circuit. At 155, the boost circuit is deactivated after the resonant frequency is established in the crystal oscillator structure. In one embodiment the boost circuit may be deactivated by switching off power to the circuit, disconnecting its output to the crystal oscillator structure, or gating its clock after the resonant frequency has been reached and is stable.

FIG. 10 is a flow chart that illustrates more details regarding the generation of the output frequency signal according to one embodiment. The act 152 of FIG. 9 may comprise activating a current ramp circuit to generate a current ramp signal comprising a current that varies between an initial current and a final current at 156. In one embodiment the current ramp signal comprises a current that varies between the initial current and the final current in a substantially linear fashion, however, the method is not so limited. At 158 of FIG. 10 the method comprises feeding the current ramp signal to a current controlled oscillator circuit to generate the output frequency signal based on the current ramp signal using the oscillator circuit.

In act 158, generating the output frequency signal with the current ramp signal using the oscillator circuit is illustrated in FIG. 11 at 160 with charging a capacitance element using the current ramp signal, and then discharging the capacitance element each time a voltage across the capacitance element reaches a threshold voltage during charging at 162. The continued charging and discharging of the capacitance element using the current ramp signal results in a generally triangular voltage waveform at the capacitance and a rectangular waveform after the SR-Flip Flops having a frequency that varies in a manner corresponding to the current ramp signal that varies between the initial current and the final current. The generation of the output frequency signal further comprises at 164 of using the voltage across the capacitance to drive comparators to generate a square wave signal having a frequency that varies across a range of frequencies. The resultant frequency output signal is the excitation signal employed by the boost circuit in establishing the resonant frequency of the crystal structure.

In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

1-21. (canceled)

22. An oscillation circuit, comprising:
a crystal oscillator structure; and
a boost circuit configured to initiate an oscillation in the crystal oscillator structure, wherein the boost circuit is configured to excite the crystal oscillator structure with an excitation signal having a frequency that varies from an initial frequency to a final frequency, the initial frequency and the final frequency defining a frequency band;
wherein the boost circuit comprises:
a current ramp circuit configured to generate a current that varies between an initial current and a final current; and
an oscillator circuit coupled to the current ramp circuit and configured to generate an oscillator signal having a frequency that varies based on a variation of the current, wherein the frequency of the oscillator signal varies from the initial frequency to the final frequency corresponding to the initial current and the final current, respectively; and
wherein the oscillator circuit comprises:
a first capacitance element connected between the current ramp circuit and a reference potential, wherein the first capacitance element is connected to the current ramp circuit at a first node, and
a first switch connected in parallel with the first capacitance element; and
a second capacitance element connected between the current ramp circuit and the reference potential, wherein the second capacitance element is connected to the current ramp circuit at a second, different node and
a second switch connected in parallel with the second capacitance element;
wherein the current from the current ramp circuit charges the first capacitance element and the second capacitance element alternately, based on the switching of the first switch and the second switch, respectively, thereby causing a voltage to increase across the first capacitance element and the second capacitance element in a generally linear fashion and thus resembling a triangular type waveform at the first capacitance element and the second capacitance element, respectively.

23. The oscillation circuit of claim 22, wherein the initial frequency is greater than zero Hertz.

24. The oscillation circuit of claim 22, wherein the current ramp circuit comprises:
a ramp generator circuit configured to generate a voltage ramp signal that varies from an initial voltage to a final voltage; and
a voltage to current converter circuit configured to convert the voltage ramp signal to a current ramp signal,
wherein the current ramp signal comprises the current that varies between the initial current and the final current, wherein the initial current and the final current correspond to the initial voltage and the final voltage, respectively.

25. The oscillation circuit of claim 22, wherein the current that varies between the initial current and the final current increases in a substantially linear manner.

26. The oscillation circuit of claim 22, wherein the current ramp signal from the current ramp circuit increases in a substantially linear fashion, wherein an increase in the current ramp signal results in an increase in a rate of charging of the first capacitance element and the second capacitance element and thus results in an increase in a frequency of the excitation signal.

27. The oscillation circuit of claim 26, wherein a slope of each successive voltage ramp of the triangular type waveform at the first capacitance element and the second capacitance element increases with the increase in a rate of charging of the first capacitance element and the second capacitance element, respectively.

28. A method of initiating oscillation in a crystal oscillator structure, comprising:
activating a boost circuit to generate an output frequency signal that varies in frequency from an initial frequency to a final frequency, thereby defining a range of frequencies; and
applying the output frequency signal to the crystal oscillator structure;
wherein the boost circuit comprises a current ramp circuit, and wherein activating the boost circuit comprises activating the current ramp circuit to generate a current ramp signal comprising a current that varies between an initial current and a final current, feeding the current ramp signal to an oscillator circuit; and generating the output frequency signal based on the current ramp signal using the oscillator circuit; and
wherein generating the output frequency signal comprises:
charging a first capacitance element and a second capacitance element alternately, using the current ramp signal, based on a switching of a first switch in parallel to the first capacitive element and a second switch in parallel to the second capacitive element, respectively;
discharging the first capacitance element and the second capacitive element each time a voltage across the respective capacitance element reaches a threshold voltage during charging,
wherein a continued charging and discharging of the first capacitance element and the second capacitive element using the current ramp signal results in a generally triangular voltage waveform across the first capacitance element and the second capacitive element, respectively, having a frequency that varies in a manner corresponding to the current ramp signal that varies between the initial current and the final current.

29. The method of claim 28, wherein the current ramp signal comprises a current that varies between the initial current and the final current in a substantially linear fashion.

30. The method of claim 28, wherein generating the output frequency signal further comprises converting the generally triangular voltage waveform across the first capacitance element and the second capacitive element to a generally rectangular waveform having the frequency that varies in a manner corresponding to the current ramp signal.

31. The method of claim 28, wherein the current ramp circuit comprises a voltage ramp circuit and a voltage to current converter, and wherein activating the current ramp circuit to generate a current ramp signal comprises:
activating the voltage ramp circuit to generate a voltage ramp signal; and
inputting the voltage ramp signal to the voltage to current converter to generate the current ramp signal.

32. The method of claim 28, further comprising deactivating the boost circuit after the applying of the output frequency signal to the crystal oscillator structure.

33. An oscillation circuit, comprising:
an oscillation system; and
a boost circuit configured to initiate an oscillation in the oscillation system,
wherein the boost circuit is configured to excite the oscillation system with an excitation signal having a frequency that varies from an initial frequency to a final frequency, the initial frequency and the final frequency defining a frequency band;
wherein the boost circuit comprises:
a ramp circuit configured to generate a quantity that varies between an initial quantity and a final quantity; and
an oscillator circuit coupled to the ramp circuit and configured to generate an oscillator signal having a frequency that varies based on a variation of the quantity, wherein the frequency of the oscillator signal varies the frequency from the initial frequency to the final frequency corresponding to the initial quantity and the final quantity, respectively; and
wherein the oscillator circuit comprises:
a first capacitance element connected between the ramp circuit and a reference potential, wherein the first capacitance element is connected to the ramp circuit at a first node and a first switch connected in parallel with the first capacitance element; and
a second capacitance element connected between the ramp circuit and the reference potential, wherein the second capacitance element is connected to the ramp circuit at a second, different node and a second switch connected in parallel with the second capacitance element;
wherein an output comprising the quantity from the ramp circuit charges the first capacitance element and the second capacitance element alternately, based on the switching of the first switch and the second switch, respectively, thereby causing a voltage to increase across the first capacitance element and the second capacitance element in a generally linear fashion and thus resembling a triangular type waveform at the first capacitance element and the second capacitance element, respectively.

34. The oscillation circuit of claim 33, wherein the oscillation system comprises one of a crystal oscillator structure, a MEMS oscillator or an electromechanical oscillator.

35. The oscillation circuit of claim 33, wherein the quantity is one of a current, a voltage or a digital word.

36. The oscillation circuit of claim 33, wherein the quantity that varies between the initial quantity and the final quantity changes in a substantially linear manner.
